(19) United States
(12) Patent Application Publication
(10) Pub. No.: US 2011/0220403 A1
(43) Pub. Date: Sep. 15, 2011

(54) SIDE PACKAGED TYPE PRINTED CIRCUIT BOARD

(75) Inventor: Hsien-Chieh Lin, Taoyuan (TW)

(73) Assignee: NAN YA PCB CORP., Taoyuan County (TW)

(21) Appl. No.: 12/762,093

(22) Filed: Apr. 16, 2010

(30) Foreign Application Priority Data
Mar. 9, 2010 (TW) TW99106716

(51) Int. Cl. H05K 1/11

(52) U.S. Cl. 174/261

(57) ABSTRACT

The invention provides a side packaged type printed circuit board. The side packaged type printed circuit board includes a circuit substrate having a surface and an adjacent side surface. An inner circuit covers a portion of the surface. A first side electrical connecting pad electrically connects to the inner circuit, wherein the first side electrical connecting pad and the inner circuit are in the same additional layer.

### CROSS REFERENCE TO RELATED APPLICATIONS

This Application claims priority of Taiwan Patent Application No. 099106716, filed on Mar. 9, 2010, the entirety of which is incorporated by reference herein.

### BACKGROUND OF THE INVENTION

1. Field of the Invention

The present invention relates to a printed circuit board, and in particular, to conductive pads of a side packaged type printed circuit board.

2. Description of the Related Art

Due to demand for miniaturized, lightweight and powerful electronic products, volume of substrates and electronic devices thereof, need to be reduced. Due to the requirements of high speed, high frequency and multifunctional semiconductor devices, the amount and density of input/output (I/O) connections thereof need to be increased. Therefore, contacts (such as solder bumps) of printed circuit boards (PCBs) and chips thereon need to be increased to improve circuit density of the PCBs while the pitch of the contacts needs to be reduced. In the conventional PCB fabricating processes, however, a steel plate may deform or solder amounts may be unstable when attempting to achieve demand requirements due to limitations for current steel plate opening and solder mask printing processes for forming the solder bumps thereon. The minimum pitch of the solder bumps of the conventional PCB is between 100 μm and 150 μm, and further reduction is not possible. Therefore, the conventional PCB can not meet high density package structure requirements.

Thus, a novel printed circuit board is desired to overcome the aforementioned

### BRIEF SUMMARY OF INVENTION

A side packaged type printed circuit board is provided. An exemplary embodiment of a side packaged type printed circuit board comprises a circuit substrate having a surface and an adjacent side surface. An inner circuit covers a portion of the surface of the circuit substrate. A first side electrical connecting pad electrically connects to the inner circuit, wherein the first side electrical connecting pad and the inner circuit are in the same additional layer.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1-10 are cross section views for fabricating one exemplary embodiment of a side packaged type printed circuit board of the invention.

FIG. 11 is a side view showing a size and pitch of one exemplary embodiment of a side electrical connecting pad of the invention.

FIG. 12 is a schematic view showing the packaging of electronic devices for one exemplary embodiment of a side packaged type printed circuit board of the invention.

### DETAILED DESCRIPTION OF INVENTION

The following description is of a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice the invention.

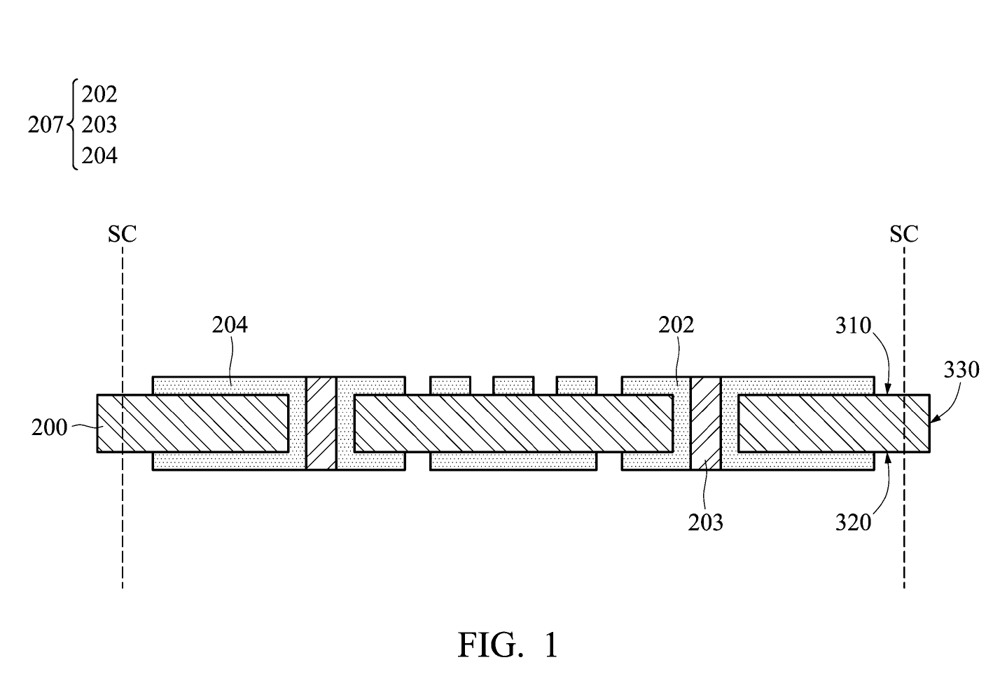

FIGS. 1-10 are cross section views for fabricating one exemplary embodiment of a side packaged type printed circuit board 500 of the invention. One exemplary embodiment of a side packaged type printed circuit board 500 uses side electrical connecting pads transversely and electrically connect to circuit layers, to extend conductive paths of the printed circuit board to side regions thereof. Therefore, solder bumps may be disposed on the side regions of the printed circuit board so that the size and the pitch of the solder bumps may be reduced. Also, the amount of package surfaces of the printed circuit board may be increased. Referring to FIG. 1, a circuit substrate 200 is provided. The circuit substrate 200 has a first surface 310, an opposite second surface 320 and side surfaces 330 adjacent to the first and second surfaces 310 and 320. In one embodiment, the amount of side surfaces 330 of the circuit substrate 200 is four. A region adjacent to the four side surface regions of the circuit substrate 200 is reserved for disposing scribe lines SC. In one embodiment, the circuit substrate 200 may comprise a paper phenolic resin, a composite epoxy, a polyimide resin or a glass fiber core material. An internal circuit structure 207 covers a portion of the first and second surfaces 310 and 320 of the circuit substrate 200, penetrating the circuit substrate 200 via the through holes. A through hole resin 203 may be formed in the through holes. In one embodiment, the internal circuit structure 207 may comprise a conductive through hole 202, the through hole resin 203 filling the conductive through hole 202 and an inner circuit 204 covering a portion of the first and second surfaces 310 and 320 of the circuit substrate 200. In one embodiment, the inner circuit 204 may comprise Ni, Au, Sn, Pb, Cu, Ag, Cr, W, combinations thereof or alloys thereof. A formation method of the inner circuit 204 may comprise entirely forming conductive layers (not shown) on the first surface 310 and the second surface 320 of the circuit substrate 200 using plating, laminating, coating or other well-known methods, respectively. In one embodiment, the first surface 310 may serve as a wafer-side surface 310, and the second surface 320 may serve as a carrier-side surface 320. Next, the inner circuit 204 is respectively formed on the first surface 310 and the second surface 320 of the circuit substrate 200 by an image transfer process comprising photoresist covering, developing, etching and photoresist striping. As shown in FIG. 1, in one embodiment, the inner circuit 204 does not cover the first and second surfaces 310 and 320 adjacent to the scribe lines SC.

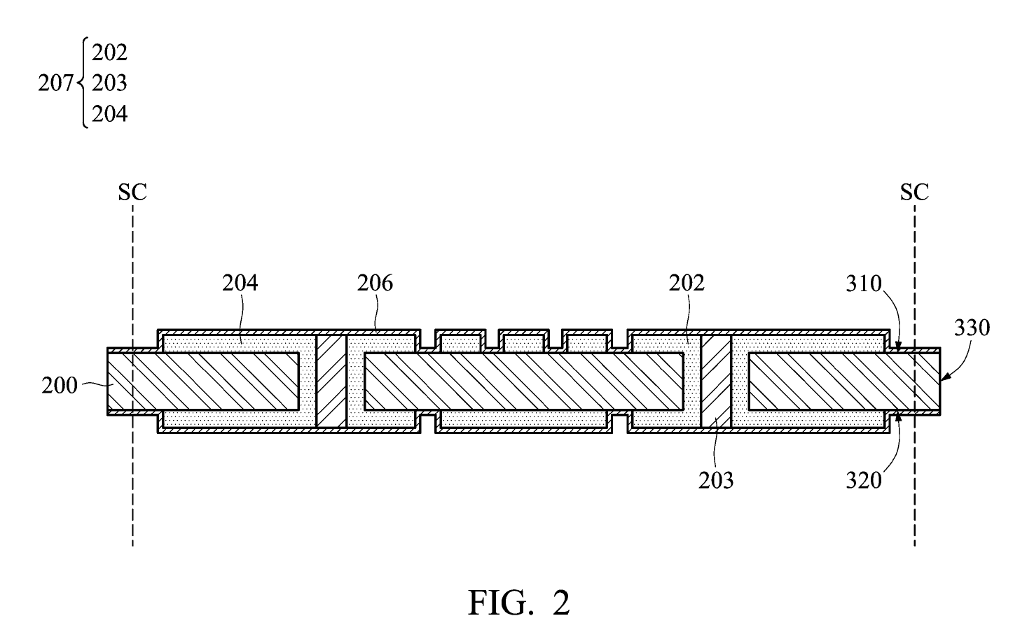

Next, referring to FIG. 2, a seed layer 206 may be conformably formed on the circuit substrate 200 by coating, chemical vapor deposition (CVD) or physical vapor deposition (PVD) methods such as sputtering. The seed layer 206 covers the inner circuit 204 and the first and second surfaces 310 and 320 exposed from the inner circuit 204. In one embodiment, the seed layer 206 may be a thin layer comprising Ni, Au, Sn, Pb, Cu, Ag, Cr, W, combinations thereof or alloys thereof. The seed layer 206 facilitates the nucleation and growing of the subsequently formed side electrical connecting pads formed by the electro plating method.

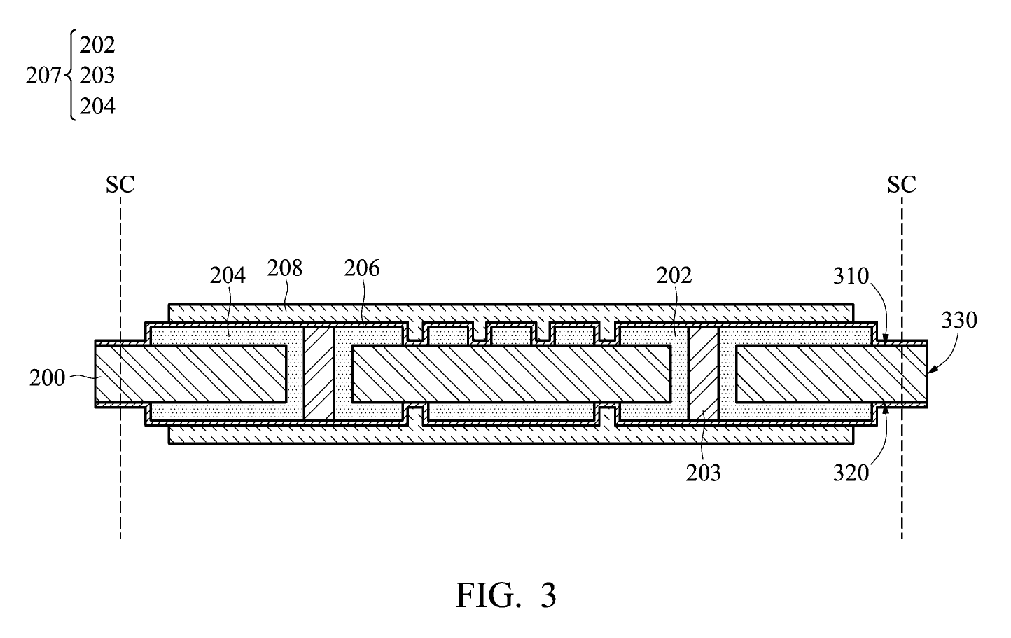

Next, referring to FIG. 3, a photoresist layer may be formed on the seed layer 206 by a pasting, coating, printing or laminating method. A photoresist developing process is then performed to form a patterned photoresist layer 208 on the seed layer 206, by exposing a portion of the seed layer 206 adjacent to the scribe lines SC and above a portion of the inner circuit 204. The patterned photoresist layer 208 defines positions and the sizes of subsequently formed side electrical connecting pads. It is noted that the thickness of the patterned photoresist layer 208 defines the thickness the subsequently formed side electrical connecting pads.

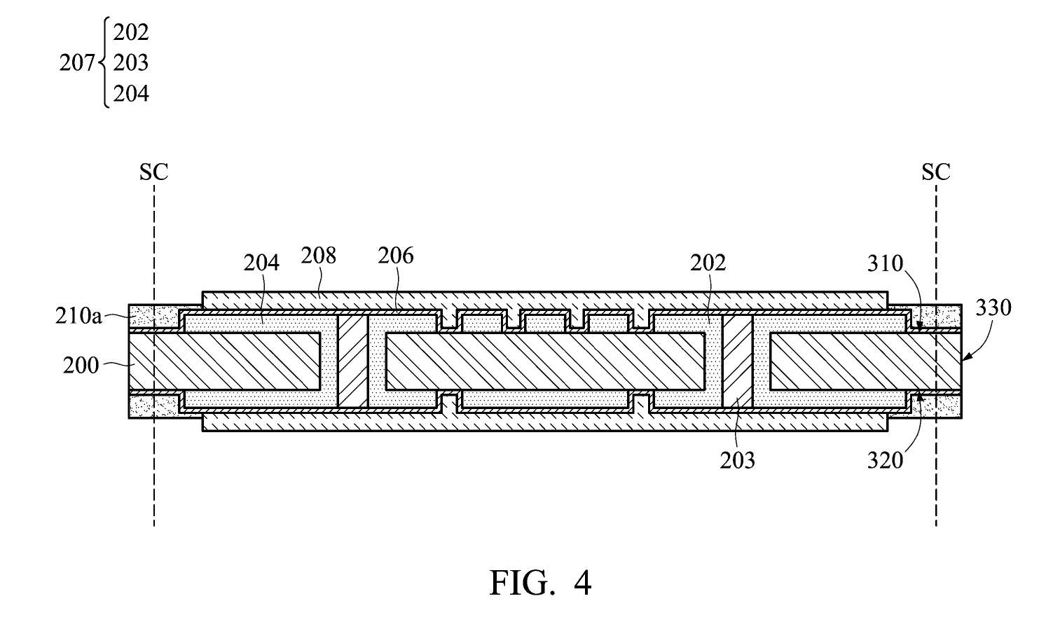

Next, referring to FIG. 4, side electrical connecting pads 210a are formed on the seed layer 206 not covered by the patterned photoresist layer 208. The inner circuit 204 and the side electrical connecting pads 210a are in the same additional layer. Also, the side electrical connecting pads 210a transversely and electrically connect to the inner circuit 204, and the side electrical connecting pads 210a transversely extend to outsides of the inner circuit 204 (adjacent to the side surfaces 330 of the circuit substrate 200). Further, a portion of the side electrical connecting pads 210a covers the inner circuit 204, above the first and second surfaces 310 and 320 adjacent to the side surfaces 330. Next, a striping process is performed to remove the patterned photoresist layer 208 while the seed layer 206, not covered by the side electrical connecting pads 210a, is removed. In one embodiment, side surfaces of terminals of the side electrical connecting pads 210a may serve as conductive pads of the inner circuit 204. The side electrical connecting pads 210a may comprise Ni, Au, Sn, Pb, Cu, Ag, Cr, W, combinations thereof or alloys thereof. In one embodiment, a thickness of the side electrical connecting pads 210a is larger than that of the inner circuit 204.

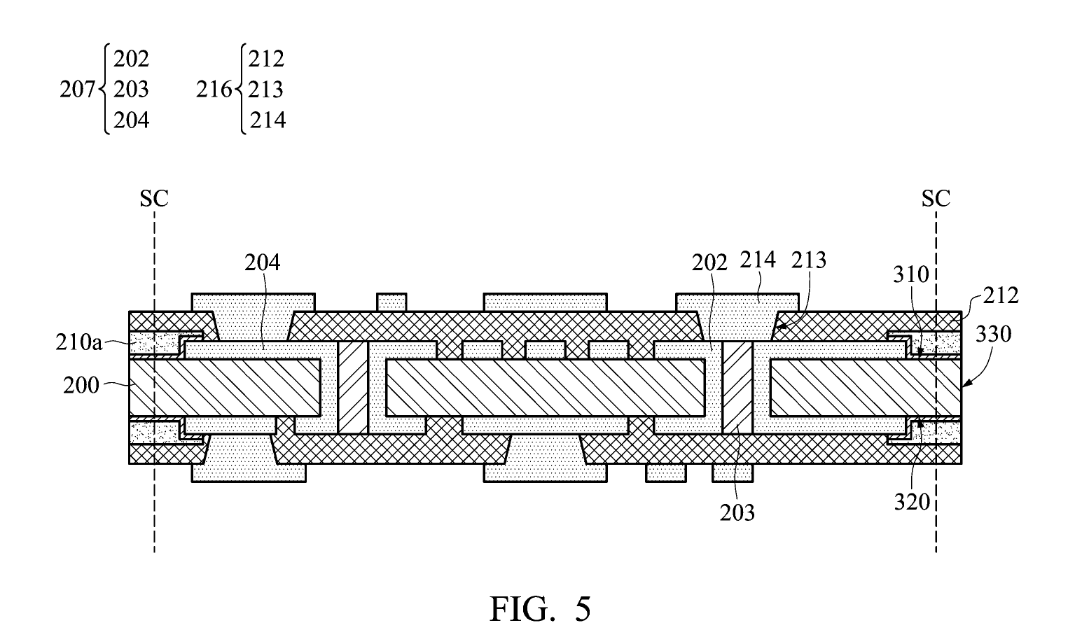

Next, referring to FIG. 5, a dielectric layer 212 is entirely formed over the first surface 310 and the second surface 320 of the circuit substrate 200 and on the internal circuit structure 207, wherein the dielectric layer 212 may comprise epoxy resin, bismaleimide triacine (BT), polyimide, an ajinomoto build-up (ABF) film, poly phenylene oxide (PPE) or polytetrafluorethylene (PTFE). Because the inner circuit 204 and the side electrical connecting pads 210a are in the same additional layer, the inner circuit 204 and the side electrical connecting pads 210a are covered by the same dielectric layer 212. Next, a plurality of blind holes, which may provide positions of conductive blind holes 213 and/or additional circuits 214 subsequently formed on the additional circuit structure 216, is formed in the dielectric layer 212 by laser drilling. Next, a seed layer is formed on the dielectric layer 212 and in the holes, wherein the conductive layer may comprise Ni, Au, Sn, Pb, Cu, Ag, Cr, W, combinations thereof or alloys thereof. Next, the conductive blind holes 213 and/or additional circuits 214 subsequently formed on the additional circuit structure 216 may be formed on the dielectric layer 212 and in the holes by a patterned process. The conductive blind holes 213 and/or additional circuits 214 are electrically connected to the internal circuit structure 207.

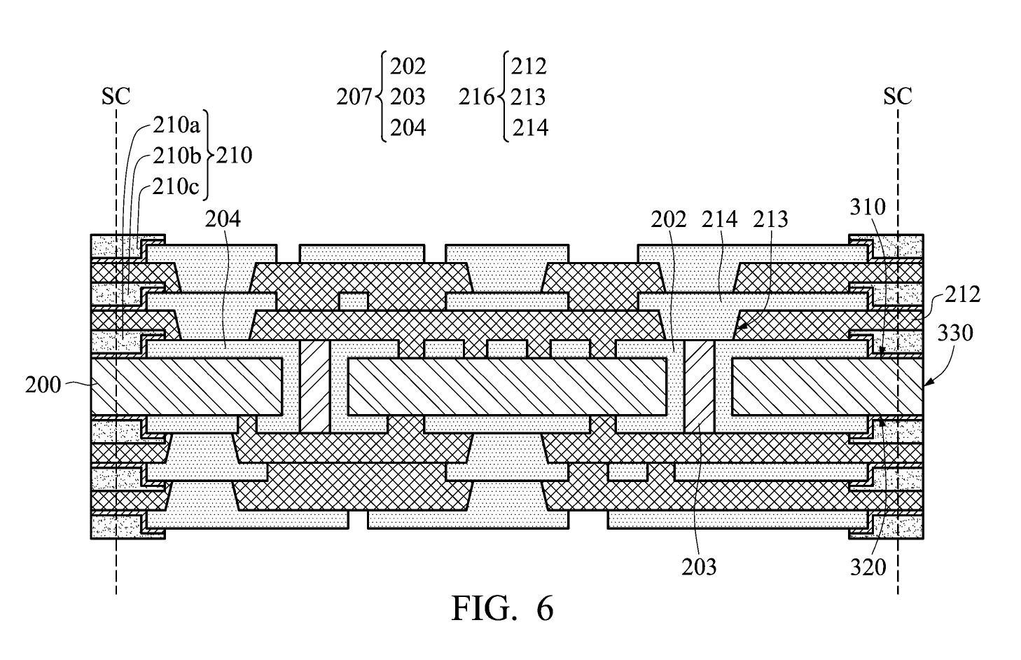

Next, referring to FIG. 6, processes as shown in FIG. 2 to FIG. 5 are repeated to form other dielectric layers 212, the conductive blind holes 213 and the additional circuits 214 on the additional circuit structure 216. Also, before forming each of the dielectric layers 212, side electrical connecting pads 210b˜210c are formed over a portion of the additional circuits 214 and respectively on the each of the dielectric layers 212 by an electro plating method to electrically connect to each of the additional circuits 214. Therefore, the conductive blind holes 213 and the additional circuits 214 may be formed by vertically laminating a plurality of the dielectric layers 212 of the additional circuit structure 216 (this embodiment shows an additional circuit structure 216 constructed by two dielectric layers 212 for brevity). Also, the side electrical connecting pads 210b˜210c respectively and transversely extend to the outside of the additional circuits 214 (adjacent to the side surfaces 330 of the circuit substrate 200). As shown in FIGS. 5 and 6, it is noted that the additional circuits 214 of the additional circuit structure 216 are not formed directly on the side electrical connecting pads 210a. In one embodiment, the side electrical connecting pads 210a˜210c may have the same materials and thickness.

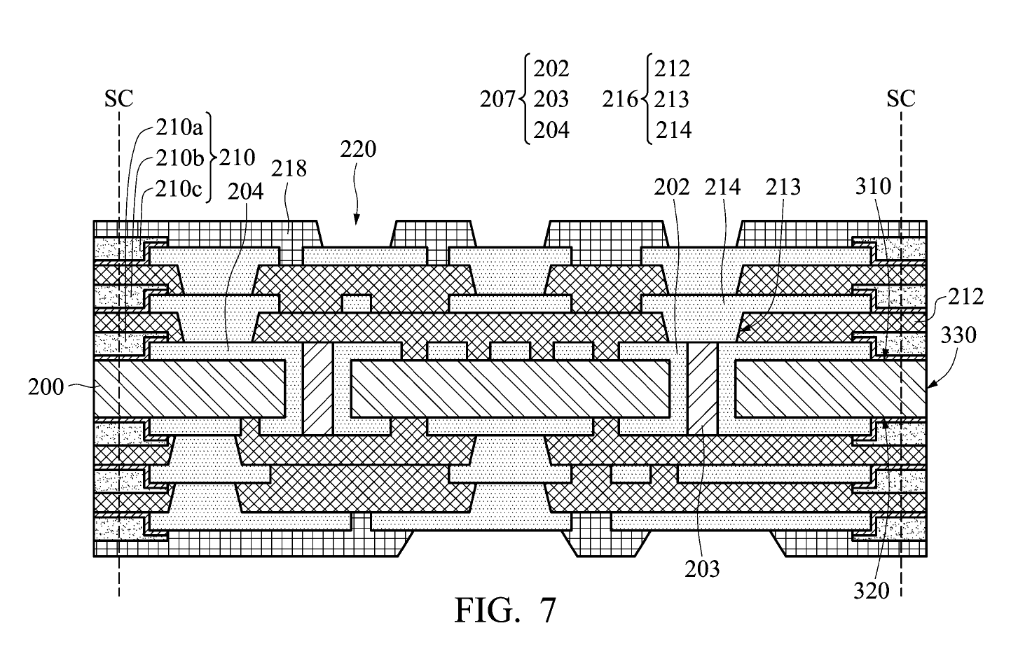

Next, referring to FIG. 7, a solder resistance insulating layer 218 may be formed on the additional circuit structure 216 by a coating, printing, pasting or laminating method. Next, a plurality of openings 220 may be optionally formed by a laser drilling, plasma etching or image transferring opening process to expose a portion of the additional circuits 214. In one embodiment, the solder resistance insulating layer 218 may comprise solder resistance materials such as a solder mask, or insulating materials comprising polyimide, an ajinomoto build-up (ABF) film or polypropylene (PP). The solder resistance insulating layer 218 may protect the underlying conductive blind holes 213 and/or additional circuits 214 from oxidation and short circuiting. Additionally, the openings 220 through the solder resistance insulating layer 218 may provide positions of subsequently formed solder bumps.

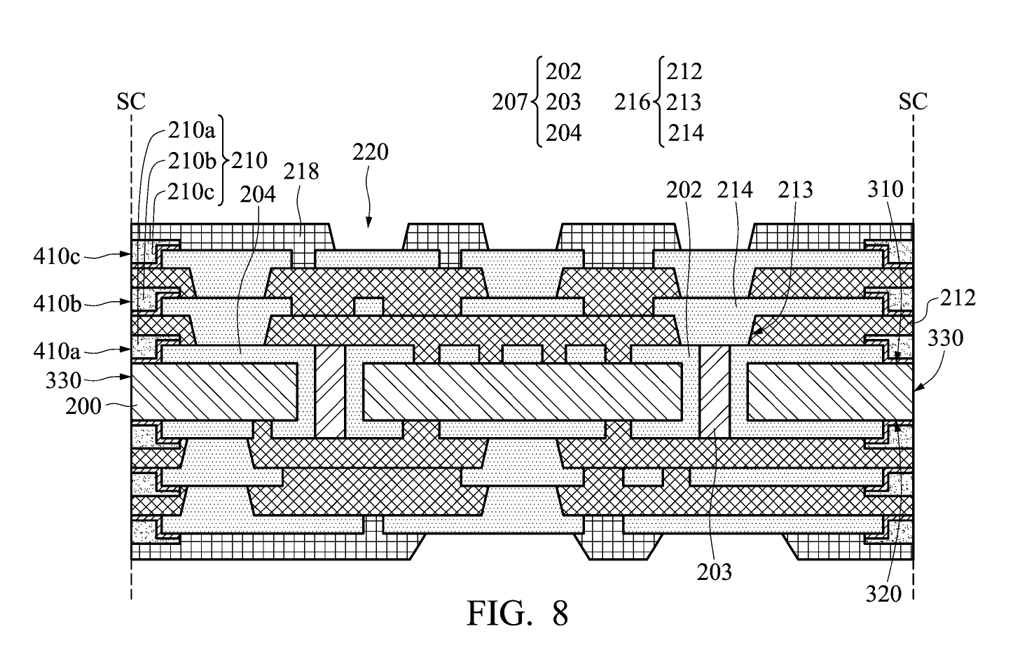

Next, referring to FIG. 8, the circuit substrate 200 is cut along the scribe lines SC by a knife cutting or other machine tooled machining methods to remove unnecessary materials and planarize surfaces of the side electrical connecting pads 210a˜210c. After performing the aforementioned processes, the side electrical connecting pads 210a˜210c with planarized surfaces are formed.

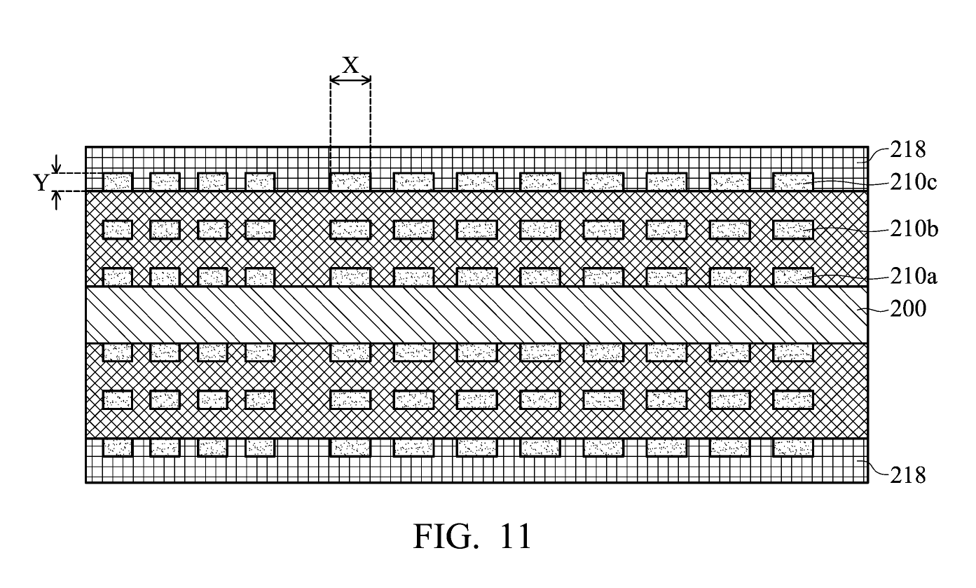

FIG. 11 is a side view showing a size and pitch of one exemplary embodiment of a side electrical connecting pad of the invention (also referred to as a top view of the side electrical connecting pads 210a˜210c). In one embodiment, the side electrical connecting pads 210a˜210c may serve as conductive pads for the inner circuit 204 and the additional circuits 214. As shown in FIG. 11, a line width X and a thickness Y of the side electrical connecting pads 210a˜210c may be defined by the size and the thickness of the patterned photoresist layer 208 as shown in FIG. 3. The pitch of the side electrical connecting pads 210a˜210c may be defined by the size of the patterned photoresist layer 208 or the thickness of the dielectric layers 212 as shown in FIG. 3. Therefore, the size of the side electrical connecting pads 210a˜210c may be precisely controlled by the aforementioned elements. Also, the size of the side electrical connecting pads 210a˜210c may be shrinked as the inner circuit 204 and the additional circuits 214.

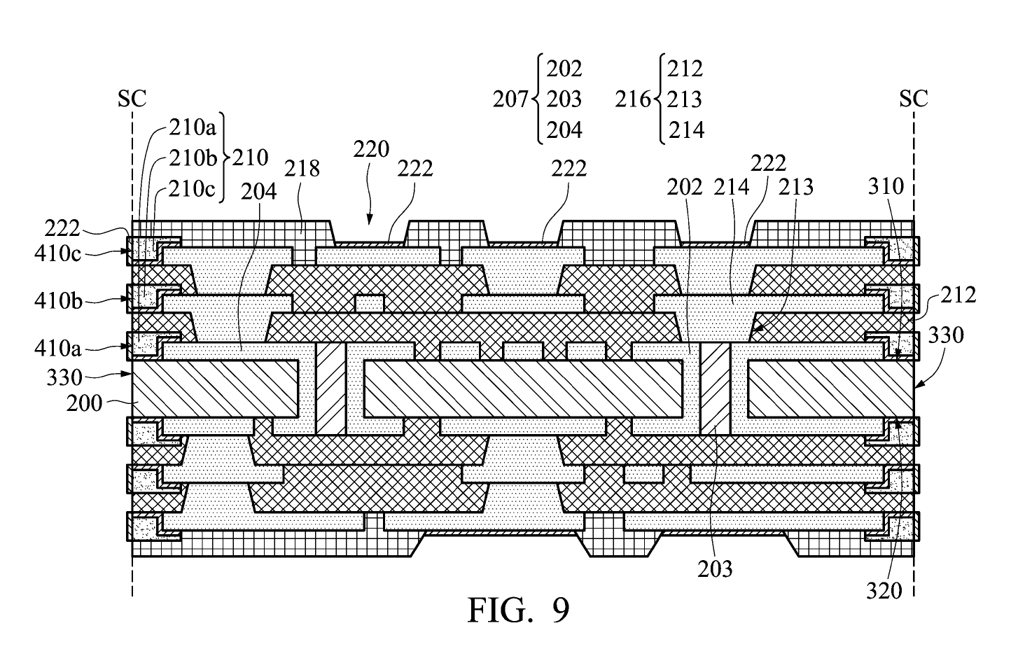

Next, referring to FIG. 9, metal protection layers 222 may be respectively formed on terminals 410a˜410c of the side electrical connecting pads 210a˜210c parallel to the side surfaces 330 of the circuit substrate 200 and on the additional circuits 214 exposed from bottom surfaces of the openings 220. In one embodiment, the metal protection layers 222 may comprise Ni, Au, Sn, Pb, Ag, Cr, W, Pd, combinations thereof or alloys thereof. The metal protection layers 222 may increase adhesion force of subsequently formed solder bumps to the side electrical connecting pads 210a˜210c and the additional circuits 214.

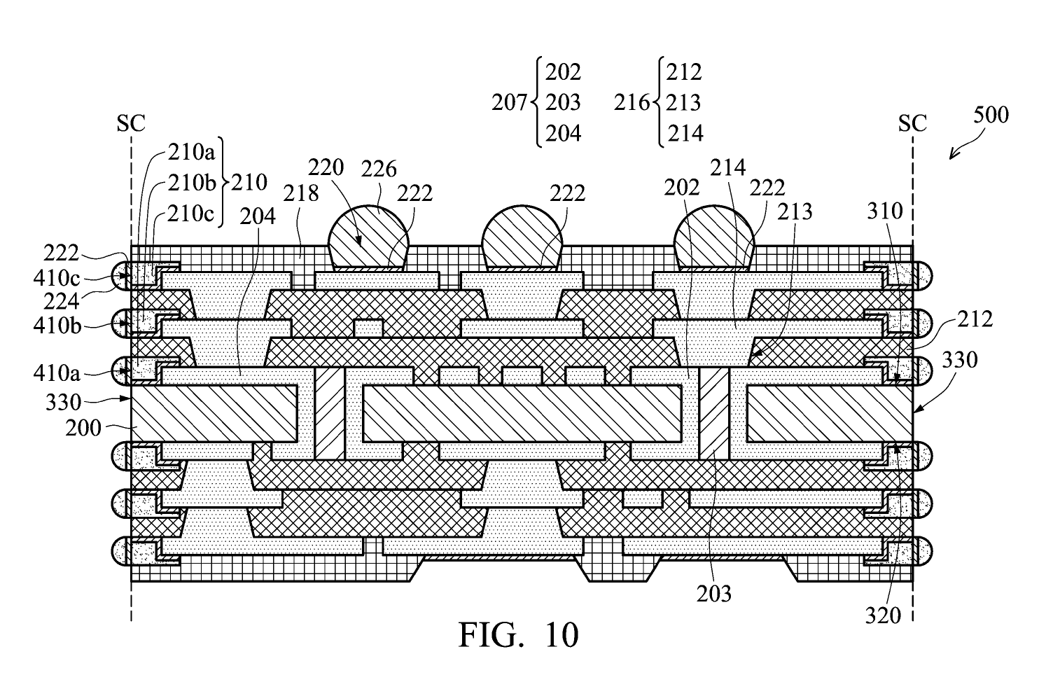

Next, referring to FIG. 10, solder bumps 224 may be formed on the metal protection layers 222 to electrically and respectively connect to the terminals 410a˜410c of the side electrical connecting pads 210a˜210c by deposition and patterning processes or printing and solder ball mount processes. In one embodiment, the solder bumps 224 may comprise Ni, Au, Sn, Pb, Cu, Al, Ag, Cr, W, Si, combinations thereof or alloys thereof. Additionally, printing molds having openings may be optionally disposed over the solder resistance insulating layer 218, wherein the formation positions of the openings of the printing molds are substantially aligned to the positions of the openings 220. Next, solder paste may be scraped or squeezed into the openings of the printing molds, covering surfaces of the solder resistance insulating layer 218 and the openings 220. Next, the solder paste on the surfaces of the solder resistance insulating layer 218 and in the openings 220 is melted by a reflow process, forming solder bumps 226 such as solder balls in the openings 220. The solder bumps 226 are electrically connected to the additional circuit structure 216. After the aforementioned fabricating process, one exemplary embodiment of a side packaged type printed circuit board 500 of the invention is completely formed.

In another embodiment, the terminals 410a˜410c of the side electrical connecting pads 210a˜210c may be directly and electrically connected to electronic devices such as capacitors or chips, through the metal protection layers 222, thereby without forming the solder bumps 224 as shown in FIG. 10. Alternatively, the solder bumps 224 as shown in FIG. 10 may be formed directly on the terminals 410a˜410c of the side electrical connecting pads 210a˜210c to electrically connect to electronic devices such as capacitors or chips, such that the metal protection layers 222, as shown in FIG. 9, do not have to be formed.

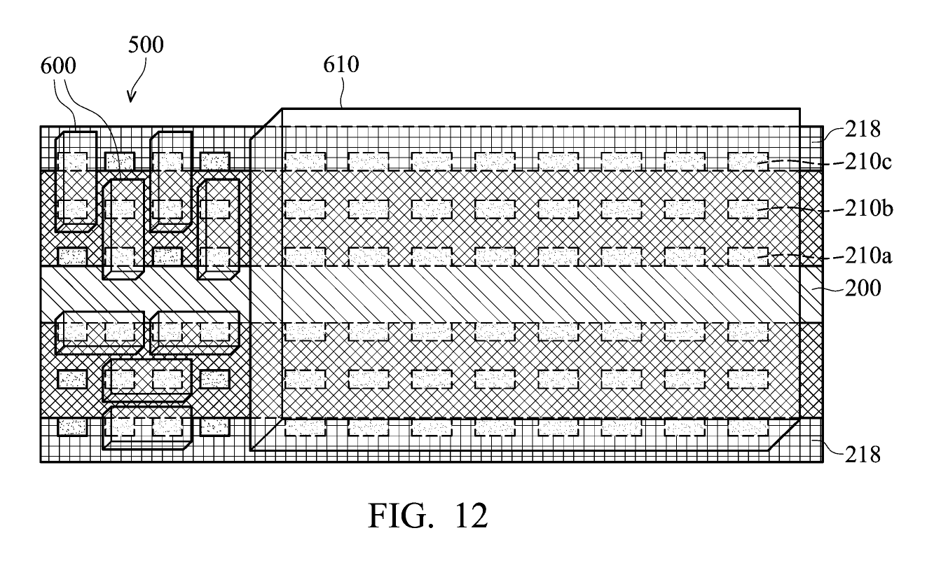

FIG. 12 is a schematic view showing the packaging of electronic devices for one exemplary embodiment of a side packaged type printed circuit board 500 of the invention. As shown in FIG. 12, an electronic device 600 such as a capacitor or an electronic device 610 such as a chip may be disposed on the side surface regions of the side packaged type printed circuit board 500, and the amount of side surface regions of the side packaged type printed circuit board 500 may reach four. One exemplary embodiment of the side packaged type printed circuit board 500 may integrate the electrical connecting pads for external connections on the side surface regions thereof, thereby substantially reducing the size and pitch of the electrical connecting pads. Therefore, more electronic devices can be disposed on the side surface regions of the side packaged type printed circuit board 500 to achieve a high density package structure.

One exemplary embodiment of the side packaged type printed circuit board 500 uses side electrical connecting pads (serves as conductive pads) to transversely and electrically connect to inner circuits therein, wherein the side electrical connecting pads and the inner circuits are in the same additional layer. The side electrical connecting pads may extend the conductive paths of the printed circuit board to the side surface regions thereof. Therefore, solder bumps may be disposed on the side surface regions of the printed circuit board, and the size and the pitch of the solder bumps may be substantially reduced. Also, the positions of the solder bumps may be precisely controlled. Additionally, the photolithography process may define the line width X and the thickness Y of the side electrical connecting pads, and the thickness of the dielectric layers may define the pitch of the side electrical connecting pads. Therefore, the pitch of the side electrical connecting pads may be controlled; for example, the pitch of the conventional solder bumps may be directly shrunk from 150 μm to 20 μm, even to 14 μm. Further, the electronic devices or chips may be disposed on the side surfaces of the printed circuit board along a direction vertical to the line width X and the thickness Y of the side electrical connecting pads. The side electrical connecting pads have small thermal expansion along the direction vertical to the line width X and the thickness Y thereof. Therefore, the side packaged type printed circuit board may have a more precise packaging size and good reliability. Compared to the conventional printed circuit board, four side surfaces of the side packaged type printed circuit board 500 may be used as packaging surfaces. Therefore, the amount of packaging surfaces of the side packaged type printed circuit board 500 may reach six (comprising the wafer-side surface, the carrier-side surface and the four side surfaces). Various electronic devices with different functions may be disposed on the four side surfaces of the printed circuit board according to requirements, to achieve a high density package structure.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A side packaged type printed circuit board, comprising:
a circuit substrate having a surface and an adjacent side surface;
an inner circuit covering a portion of the surface of the circuit substrate; and
a first side electrical connecting pad electrically connecting to the inner circuit, wherein the first side electrical connecting pad and the inner circuit are in the same additional layer.

2. The side packaged type printed circuit board as claimed in claim 1, further comprising:
an additional circuit disposed on the inner circuit, electrically connecting to the inner circuit; and
a second side electrical connecting pad electrically connecting to the additional circuit, wherein the second side electrical connecting pad and the additional circuit are in the same additional layer.

3. The side packaged type printed circuit board as claimed in claim 2, further comprising:
a solder resistance insulating layer disposed on the additional circuit, wherein the solder resistance insulating layer has an opening;
a metal protective layer disposed on a bottom surface of the opening; and
a solder bump disposed on the metal protective layer.

4. The side packaged type printed circuit board as claimed in claim 1, wherein the first side electrical connecting pad and the inner circuit are covered by a single dielectric layer.

5. The side packaged type printed circuit board as claimed in claim 4, wherein the first and second side electrical connecting pads are separated by the dielectric layer while the inner and additional circuits are separated by the dielectric layer.

6. The side packaged type printed circuit board as claimed in claim 2, wherein a thickness of the first side electrical connecting pad is larger than that of the inner circuit, and a thickness of the second side electrical connecting pad is larger than that of the additional circuit.

7. The side packaged type printed circuit board as claimed in claim 2, further comprising a plurality of metal protective layers disposed on terminals of the first and second side electrical connecting pads parallel to the side surface of the circuit substrate.

8. The side packaged type printed circuit board as claimed in claim 2, wherein a portion of the surface adjacent to the side surface of the circuit substrate is exposed from the inner circuit, and the first and second side electrical connecting pads are disposed above the portion of the surface adjacent to the side surface of the circuit substrate which is exposed from the inner circuit.

9. The side packaged type printed circuit board as claimed in claim 2, wherein the first side electrical connecting pad transversely extends to an outside of the inner circuit, and the second side electrical connecting pad transversely extends to an outside of the additional circuit.

10. The side packaged type printed circuit board as claimed in claim 2, further comprising a plurality of solder bumps disposed on terminals of the first and second side electrical connecting pads parallel to the side surface of the circuit substrate.

11. The side packaged type printed circuit board as claimed in claim 7, further comprising a plurality of solder bumps disposed on terminals of the first and second side electrical connecting pads parallel to the side surface of the circuit substrate.
